(19) United States
(12) Patent Application Publication
(10) Pub. No.: US 2009/0124084 A1
(43) Pub. Date: May 14, 2009

(54) FABRICATION OF SUB-RESOLUTION FEATURES FOR AN INTEGRATED CIRCUIT

(76) Inventors: Elliot Tan, Portland, OR (US); James Jeong, Portland, OR (US)

Correspondence Address: INTEL CORPORATION;c/o CPA Global, P.O. BOX 52050, MINNEAPOLIS, MN, 55402, US

(21) Appl. No.: 11/940,121

(22) Filed: Nov. 14, 2007

(51) Int. Cl. H01L 21/467

(52) U.S. Cl. 438/699; 257/E21.486

(57) ABSTRACT

A method for fabricating sub-resolution features on an integrated circuit comprises depositing a hard mask layer on a dielectric layer of a semiconductor substrate, patterning the hard mask layer to form hard mask structures that define trenches, etching trenches in the dielectric layer through the hard mask structures, thereby forming a first set of dielectric structures on the substrate, depositing a conformal layer on the substrate and the first set of dielectric structures, etching the conformal layer to form spacers adjacent to the first set of dielectric structures, depositing a second dielectric layer within the trenches, thereby forming a second set of dielectric structures on the substrate, and etching the spacers to form sub-resolution trenches between the dielectric structures of the first and second set.

### BACKGROUND

In the manufacture of integrated circuits, metal interconnects are used to electrically couple devices, such as transistors, inductors, and diodes, that are formed on the surface of a semiconductor substrate. Metal interconnects are fabricated using a damascene process. In such a process, a dielectric layer is deposited and patterned to form a trench that defines the metal interconnect. A copper layer may then be deposited within the trench, along with barrier and/or adhesion layers, and a chemical mechanical polishing (CMP) process may follow to planarize the deposited copper layer. The CMP process also removes excess metal from outside the boundaries of the trench, yielding a metal interconnect confined within the trench of the dielectric layer.

Photolithography is currently used to pattern the trench in the dielectric layer. A typical lithographic process includes depositing a layer of photoresist material on the surface of the dielectric layer, exposing the photoresist material to ultraviolet (UV) radiation through a patterned optical mask, baking the photoresist, and then developing the photoresist. This yields a hard mask on the surface of the dielectric layer that leaves a portion of the dielectric layer exposed to define the trench. An etching process follows to remove the exposed portion of the dielectric layer and form the trench.

As integrated circuit dimensions continue to decrease, there is a limit to how far these trenches can be scaled down based on the resolution limitations of the UV radiation. More specifically, at the 32 nanometer (nm) and 22 nm nodes, current lithography technologies cannot achieve the required dimensions. Therefore, alternate processes are needed to fabricate features at these sub-resolution dimensions.

### BRIEF DESCRIPTION OF THE DRAWINGS

FIG. 1 is a method of forming sub-resolution trenches in accordance with an implementation of the invention.

FIGS. 2A through 2F illustrate structures that are formed when the method of FIG. 1 is carried out.

FIG. 3 is another method of forming sub-resolution trenches in accordance with an implementation of the invention.

### DETAILED DESCRIPTION

Described herein are systems and methods of fabrication sub-resolution features for an integrated circuit. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide a fabrication process for sub-resolution features in a dielectric layer, namely, for trenches in a dielectric layer having “sub-resolution” dimensions that are not achievable using conventional photolithographic processes. The methods disclosed herein use a novel deposition and etch process that overcomes the limitations of conventional photolithography.

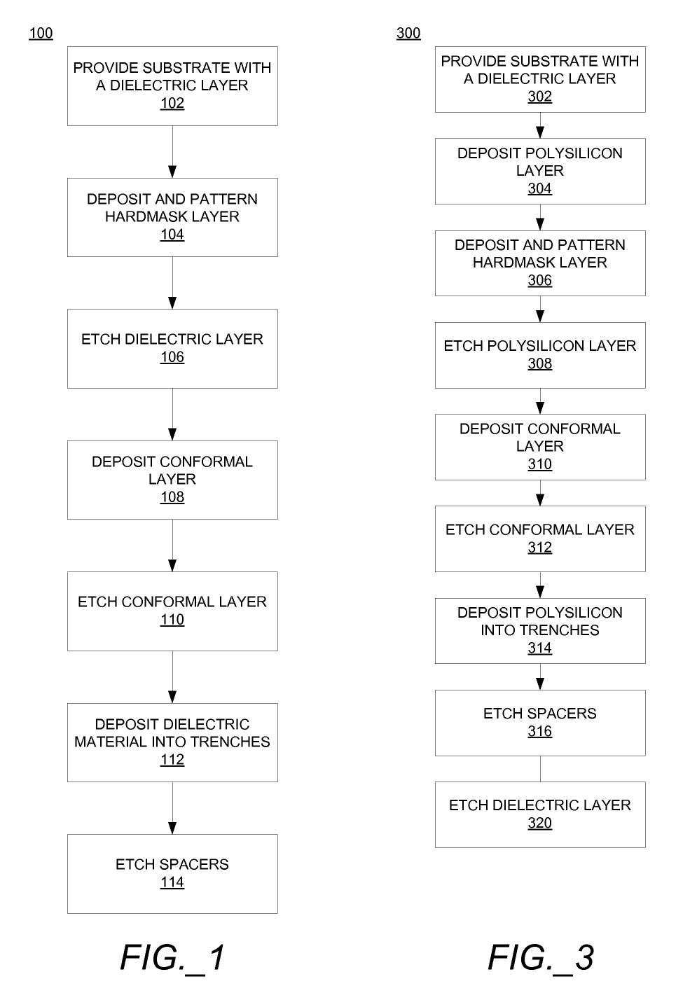

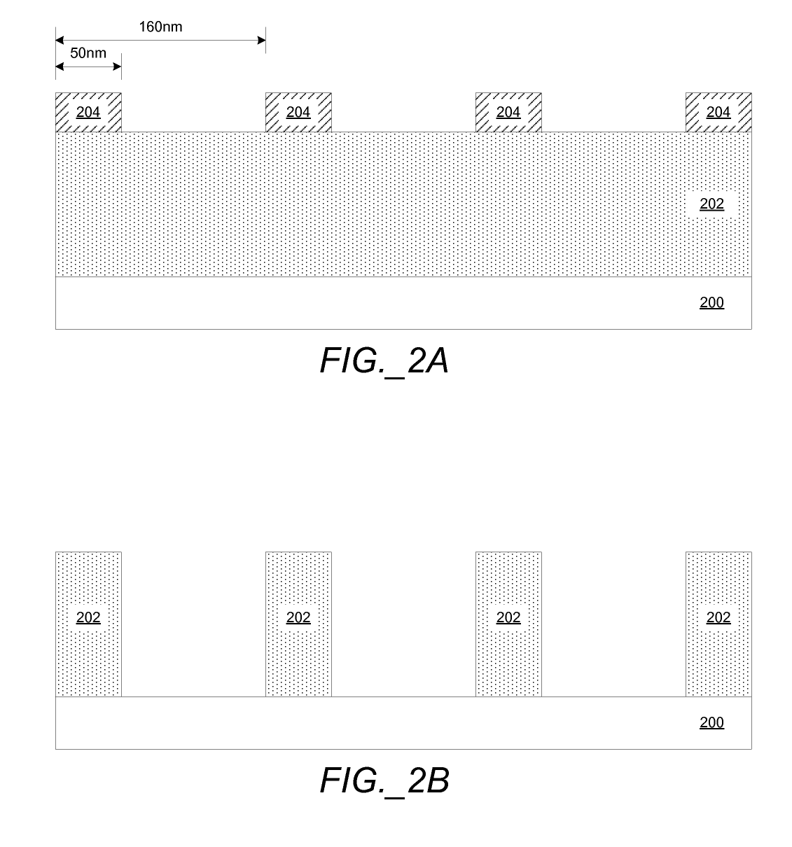

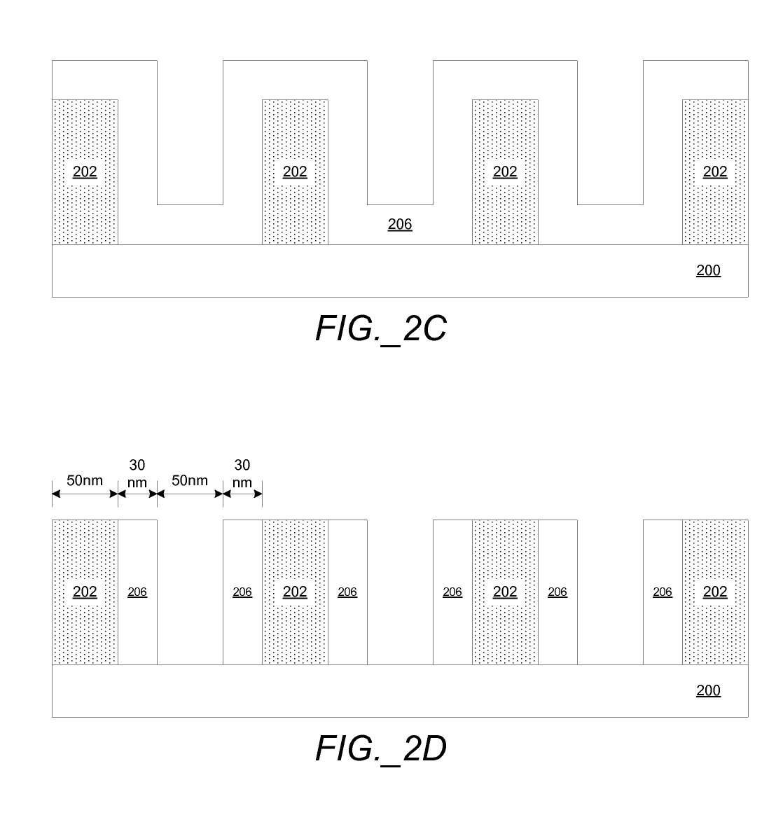

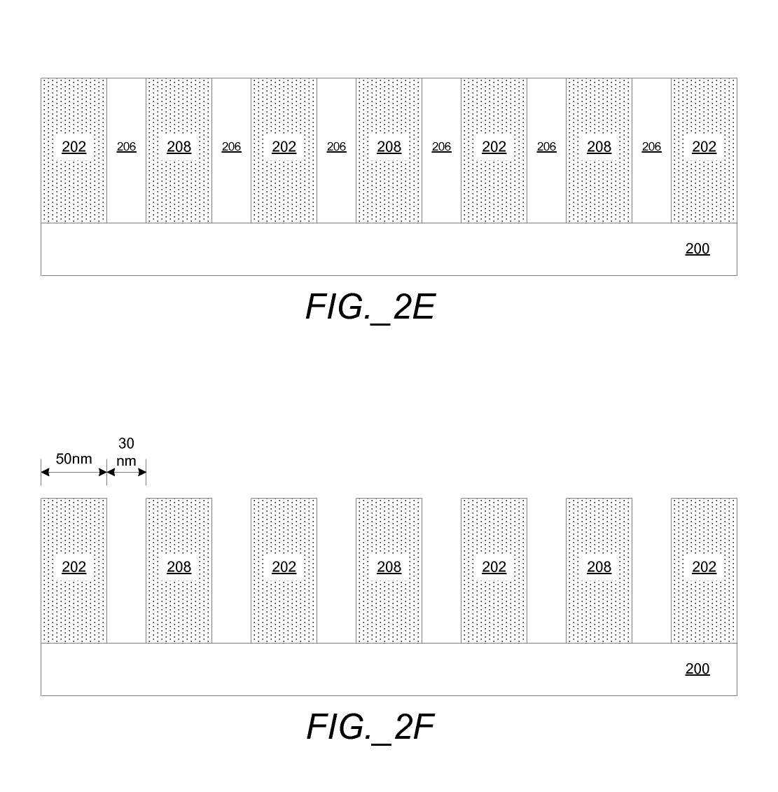

FIG. 1 is a fabrication process 100 to form sub-resolution trenches within a dielectric layer in accordance with an implementation of the invention. The trenches may be used in a damascene process to form sub-resolution metal interconnects for scaled down integrated circuits, such as circuits built using a 32 nm process or below. In the specific implementation described, the trenches have a width of around 30 nm and a pitch of around 80 nm. As will be recognized by those of skill in the art, however, alternate dimensions may be used that vary from the dimensions provided in the method 100 of FIG. 1. FIGS. 2A through 2F illustrate structures that are formed as the method 100 is carried out.

The method 100 of FIG. 1 begins by providing a substrate upon which a su b-resolution feature may be fabricated (process 102 of method 100). The substrate is typically a semiconductor substrate formed using a single-crystal silicon or a silicon-on-insulator (SOI) substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention. Integrated circuit devices such as transistors, inductors, and diodes may be formed on the surface of the semiconductor substrate or within layers deposited upon the substrate surface.

The semiconductor substrate includes at least one layer of a dielectric material on its surface. The dielectric layer may be formed using materials known for the applicability in dielectric layers for integrated circuit structures, such as one or more of silicon dioxide (SiO₂), fluorinated SiO₂, carbon doped oxide (CDO), silicon nitride (SiN), tetraethylorthosilicate (TEOS), borophosphosilicate glass (BPSG), fluorosilicate glass (FSG), spin on glass (SOG), low-k materials, high-k materials, organic polymers such as perfluorocyclobutane or polytetrafluoroethylene, inorganic polymers, and organosilicates such as silsesquioxane, siloxane, or organosilicate glass. The dielectric layer may include pores or other voids to further reduce its dielectric constant.

A hard mask layer is deposited and patterned on the surface of the dielectric layer (104). The patterned hard mask layer defines trenches in the dielectric layer. The material used for the hard mask layer may be a material conventionally used to form masking structures, including but not limited to silicon nitride, titanium, titanium nitride, amorphous carbon, and other similar materials.

A photolithographic process is used to pattern the hard mask at dimensions that are achievable using conventional photolithography. For instance, in the implementation described herein, the hard mask layer is patterned to form mask structures that are around 50 nm wide with a pitch of around 160 nm. The length of each hard mask structure will vary greatly based on many factors, including but not limited to the varying lengths of the various metal interconnects being formed.

FIG. 2A illustrates a substrate 200 having a dielectric layer 202 deposited thereon. As described above, the substrate 200 may be a silicon or SOI substrate and the dielectric layer 202 may be any of the above mentioned materials, including but not limited to, silicon dioxide or carbon doped oxide. Hard mask structures 204, formed of a material such as silicon nitride, are formed on the dielectric layer 202 using a deposition and lithographic patterning process. The hard mask structures 204 have a width of around 50 nm. The pitch, which is measured from the start of one hard mask structure 204 to the start of the next hard mask structure 204, is around 160 nm. As such, trenches that are around 110 nm are defined between each pair of hard mask structures 204. Again, the 50 nm width and 160 nm pitch are attainable using photolithographic processes.

Using the hard mask structures as an etch mask, an etching process is carried out on the exposed portions of the dielectric layer to form trenches (106). Conventional etching processes suitable for use on dielectric materials may be used, including known wet and dry etch chemistries that use fluorine containing carbon compounds, such as CF₄, C₄F₈, and C₄F₆. After the etching process is complete and the hard mask structures are removed, the resulting structure consists of a substrate having multiple dielectric structures on its surface. The dielectric structures have widths of approximately 50 nm and pitches of approximately 160 nm.

FIG. 2B illustrates multiple dielectric structures 202 on the substrate 200 after the etching process is complete and the hard mask structures 204 are removed. Again, the dielectric structures 202 have widths of approximately 50 nm. Because the pitch is approximately 160 nm, the trenches between the dielectric structures 202 are approximately 110 nm wide.

A conformal layer is now deposited over the substrate and over the dielectric structures (108). The conformal layer may be deposited using a process such as atomic layer deposition (ALD) or chemical vapor deposition (CVD) and may be carried out in a high temperature diffusion furnace. Materials that may be used for the conformal layer include, but are not limited to, silicon nitride. In accordance with implementations of the invention, the thickness of the conformal layer may be approximately 30 nm.

FIG. 2C illustrates the deposition of a conformal layer 206 on the substrate 200 and the dielectric structures 202. The thickness of the conformal layer 206 is approximately 30 nm. The conformal layer 206 may be formed of silicon nitride.

An etching process follows the conformal layer deposition to etch the conformal layer and form spacers adjacent to the dielectric structures (110). The etching process used is generally an anisotropic process that reduces the height of the conformal layer without substantially impacting its width. The etching process used may be any wet or dry anisotropic etch chemistry suitable for use on the conformal layer material, which is generally silicon nitride. The etch is carried out until the substrate is exposed, yielding spacers adjacent to the dielectric structures. Etch processes that may be used on the conformal layer include, but are not limited to, HBr, NF₃, and other similar etch chemistries.

FIG. 2D illustrates the result of the etch process carried out in the conformal layer 206. As shown, the anisotropic etch process reduces the height of the conformal layer 206 while maintaining its approximately 30 nm thickness of the sidewalls of the dielectric structures 202. The end result is the formation of spacers 206 adjacent to the dielectric structures 202. As shown, the dielectric structures 202 are approximately 50 nm and the spacers 206 are approximately 30 nm. And because the pitch is 160 nm, the trenches that exist between the spacers are approximately 50 nm.

Next, a second dielectric layer is deposited onto the substrate to fill in the trenches that exist between the spacers (112). The material used in the second dielectric layer may be the same as the material chosen for the initial dielectric layer that was etched to form the 50 nm dielectric structures. Conventional dielectric deposition processes may be used, such as ALD or CVD. A planarization process may follow the dielectric layer deposition to remove excess dielectric material from the substrate, thereby forming a second set of dielectric structures that are confined within the trenches and exposing the top surfaces of the spacers.

FIG. 2E illustrates the substrate 200 after the trenches between the spacers 206 have been filled with a second set of dielectric structures 208. Because the trenches have a width of approximately 50 nm, each of the dielectric structures 208 has a width of approximately 50 nm, which matches the approximately 50 nm width of the first dielectric structures 202.

Finally, a second etch process is carried out to remove the spacers from in between the dielectric structures (114). A conventional wet or dry etching process suitable for use on the spacer material may be used. For instance, if the spacers are formed using silicon nitride, a wet etch chemistry containing hydrofluoric acid may be applied to remove the spacers. Removal of the spacers using an etching process produces sub-resolution trenches between the dielectric structures. These trenches have a width of approximately 30 nm, matching the width of the spacers that were removed.

The substrate now holds an array of dielectric structures that are separated by trenches. The dielectric structures have an approximate width of 50 nm and the trenches have an approximate width of 30 nm, therefore, the dielectric structures have an effective pitch of 80 nm. Accordingly, sub-resolution trenches have been fabricated within a dielectric layer in accordance with an implementation of the invention. The trenches may be used in a damascene process to form sub-resolution metal interconnects for scaled down integrated circuits, such as circuits built using a 32 nm process or below.

FIG. 2F illustrates the substrate 200 after the spacers 206 have been removed using an etch process. As shown, each of the dielectric structures 202/208 has a width of approximately 50 nm. The pitch is now effectively 80 nm, since the distance from the start of one dielectric structure (e.g., layer 202) to the start of the next dielectric structure (e.g., layer 208) is approximately 80 nm. As such, this is effectively a pattern of 50 nm dielectric structures at an 80 nm pitch, or equivalently, a pattern of 30 nm trenches at an 80 nm pitch.

In further implementations of the invention, as will be recognized by those of skill in the art, the final width and pitch of the dielectric structures may be controlled by the width of the initial hard mask structures and the thickness of the conformal layer.

In an alternate implementation of the invention, a masking layer may be patterned using the above described methods to define trenches that are approximately 30 nm. This patterned masking layer may then be used as a hard mask to etch an underlying dielectric layer to form the sub-resolution trenches.

For instance, in an implementation of the invention described in FIG. 3, a method 300 for fabricating sub-resolution trenches begins by providing a substrate upon which a sub-resolution feature may be fabricated (process 302 of method 300). The substrate is typically a semiconductor substrate formed using a single-crystal silicon or a silicon-on-insulator (SOI) substructure. The semiconductor substrate includes at least one layer of a dielectric material on its surface.

Next, a polysilicon layer is blanket deposited on the surface of the dielectric layer (304). Conventional deposition methods for polysilicon may be used.

A hard mask layer is then deposited and patterned on the surface of the polysilicon layer (306). The material used for the hard mask layer may be a material conventionally used to form masking structures, including but not limited to silicon nitride, titanium, titanium nitride, amorphous carbon, and other similar materials.

A photolithographic process is used to pattern the hard mask at dimensions that are achievable using conventional photolithography. In an implementation of the invention, the hard mask layer is patterned to form hard mask structures that are around 50 nm wide with a pitch of around 160 nm.

Using the hard mask structures as an etch mask, an etching process is carried out to remove exposed portions of the polysilicon layer (308). Conventional etching processes suitable for use on polysilicon may be used. After the etching process is complete and the hard mask structures are removed, the resulting structure consists of a substrate having multiple polysilicon structures formed on the surface of the dielectric layer. The polysilicon structures have widths of approximately 50 nm and pitches of approximately 160 nm.

A conformal layer, such as silicon nitride, is deposited over the substrate and over the polysilicon structures using conventional techniques (310). In accordance with implementations of the invention, the thickness of the conformal layer may be approximately 30 nm.

An etching process follows the conformal layer deposition to etch the conformal layer and form spacers adjacent to the polysilicon structures (312). The etching process used is generally an anisotropic process that reduces the height of the conformal layer without substantially impacting its width. The etch is carried out until the substrate is exposed, yielding spacers adjacent to the polysilicon structures. The spacers are approximately 30 nm thick and are separated by a trench that is approximately 50 nm wide due to the 160 nm pitch.

Another layer of polysilicon is then deposited onto the substrate to fill in trenches that exist between the spacers (314). A planarization process may follow to remove excess polysilicon material from the substrate, thereby forming a second set of polysilicon structures that are confined to the trenches and exposing the top surfaces of the spacers.

Another etch process is carried out to remove the spacers from in between the polysilicon structures (316). Removal of the spacers produces sub-resolution trenches between the polysilicon structures. These trenches have a width of approximately 30 nm, which matches the width of the spacers that were removed. The substrate now holds an array of 50 nm polysilicon structures that are separated by 30 nm trenches, yielding an effective pitch of 80 nm.

A final etch process is carried out using the polysilicon structures as a hard mask to etch the underlying dielectric layer (318). The polysilicon structures are also removed, yielding 50 nm dielectric structures separated by sub-resolution 30 nm trenches. As such, the dielectric structures have an effective pitch of 80 nm.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
depositing a hard mask layer on a dielectric layer of a semiconductor substrate;
patterning the hard mask layer to form hard mask structures that define trenches;
etching trenches in the dielectric layer through the hard mask structures, thereby forming a first set of dielectric structures on the substrate;
depositing a conformal layer on the substrate and the first set of dielectric structures;
etching the conformal layer to form spacers adjacent to the first set of dielectric structures;
depositing a second dielectric layer within the trenches, thereby forming a second set of dielectric structures on the substrate; and
etching the spacers to form sub-resolution trenches between the dielectric structures of the first and second set.

2. The method of claim 1, wherein the semiconductor substrate is selected from the group consisting of silicon, SOI, germanium, indium antimonide, lead telluride, indium arsenide, indium phosphide, gallium arsenide, and gallium antimonide.

3. The method of claim 1, wherein the dielectric layer is selected from the group consisting of SiO₂, fluorinated SiO₂, CDO, SiN, TEOS, BPSG, FSG, SOG, a low-k material, a high-k material, an organic polymer, perfluorocyclobutane, polytetrafluoroethylene, an inorganic polymer, an organosilicate, silsesquioxane, siloxane, and organosilicate glass.

4. The method of claim 1, wherein the hard mask layer comprises silicon nitride, titanium, titanium nitride, or amorphous carbon.

5. The method of claim 1, wherein the patterning of the hard mask layer is carried out using a photolithographic process.

6. The method of claim 1, wherein the hard mask structures are approximately 50 nm wide and have a pitch of approximately 160 nm.

7. The method of claim 1, wherein the etching of the trenches comprises using a wet etch chemistry to etch the dielectric layer.

8. The method of claim 1, further comprising removing the hard mask structures after the etching of the trenches in the dielectric layer.

9. The method of claim 1, wherein the depositing of the conformal layer comprises using an ALD or CVD process to deposit a conformal layer of silicon nitride.

10. The method of claim 1, wherein the conformal layer is approximately 30 nm thick.

11. The method of claim 1, wherein the etching of the conformal layer comprises using an anisotropic etching process to etch the conformal layer.

12. The method of claim 1, further comprising:
performing a planarization process after the second dielectric layer has been deposited to confine the second dielectric layer within the trenches, thereby forming the second set of dielectric structures on the substrate.

13. The method of claim 1, wherein the etching of the spacers to form sub-resolution trenches comprises applying hydrofluoric acid to the spacers.

14. A method comprising:
depositing a hard mask layer on a dielectric layer of a semiconductor substrate;
patterning the hard mask layer to form hard mask structures that define trenches, wherein the hard mask structures are approximately 50 nm wide and have a pitch of approximately 160 nm;
etching trenches in the dielectric layer through the hard mask structures to form a first set of dielectric structures on the substrate, wherein each of the dielectric structures of the first set is approximately 50 nm wide;
depositing a conformal layer on the substrate and the first set of dielectric structures that is approximately 30 nm thick;
etching the conformal layer to form spacers adjacent to the first set of dielectric structures, wherein each of the spacers is approximately 30 nm wide;
depositing a second dielectric layer on the substrate;
planarizing the second dielectric layer to confine the second dielectric layer within the trenches, thereby forming a second set of dielectric structures on the substrate, wherein each of the dielectric structures of the second set is approximately 50 nm wide; and
etching the spacers to form sub-resolution trenches between the dielectric structures of the first and second set, wherein the sub-resolution trenches are approximately 30 nm wide.

15. The method of claim 14, wherein the conformal layer comprises silicon nitride.
